(19) United States
(12) Patent Application Publication
(10) Pub. No.: US 2026/0352118 A1
(43) Pub. Date: Nov. 5, 2026

(54) ELECTRONIC MODULE AND ARRANGEMENT

(71) Applicant: TDK Europe GmbH, München (DE)

(72) Inventors: Martin Lauersdorf, Knittlingen (DE); Shinichiro Nishizawa, München (DE)

(21) Appl. No.: 19/486,641

(22) PCT Filed: Jul. 17, 2024
(86) PCT No.: PCT/EP2024/070262

§ 371 Date: Nov. 21, 2025

(30) Foreign Application Priority Data
Jul. 25, 2023 (DE) 10 2023 119 666.9

(51) Int. Cl. H02M 7/537; H02M 1/12; H02M 1/44; H02M 7/00; H05K 7/14; H05K 7/20

(52) U.S. Cl. CPC H02M 7/537; H02M 1/123; H02M 1/126; H02M 1/44; H02M 7/003; H05K 7/1432; H05K 7/209

(57) ABSTRACT

The electronic module (1) comprises at least one functional circuit component (10), a module body (2), a first interface (6) configured to electrically connect to a power module (91) and a second interface (7) configured to electrically connect to a power supply (92 ). The electronic module (1) further comprises a first capacitance unit (3) configured to reduce an external high-frequency noise and a second capacitance unit (4) configured to reduce an external low-frequency noise such that the first and second capacitance units (3, 4) form an EMC filter structure. The first capacitance unit (3), the second capacitance unit (4) and the functional circuit component (1) are integrated in the module body (2). The electronic module (1) may comprise a cooling plate (11) configured to dissipate heat from the functional circuit component (10) to a cooling body (8). The cooling plate (11) may further be configured to shield the functional circuit component (10) from noise.

### CROSS-REFERENCE TO RELATED APPLICATIONS

This application is a U.S. National Stage of International Application No. PCT/EP2024/070262, filed Jul. 17, 2024, which claims the benefit of Germany Patent Application No. 102023119666.9, filed Jul. 25, 2023, both of which are incorporated herein by reference in their entireties.

### FIELD OF THE INVENTION

The invention relates to an electronic module and to an arrangement comprising such an electronic module.

### BACKGROUND OF THE INVENTION

The patent document WO 2021/197956 A1 refers to a DC-link component an increased electromagnetic compatibility.

One problem to be solved is, inter alia, to specify an improved electronic module that is characterized in particular by reduced size and weight as well as improved noise reduction and heat dissipation. Another problem to be solved is, inter alia, to specify an arrangement comprising such an electronic module.

These tasks are solved by an electronic module comprising the features of independent claim 1 and by an arrangement comprising the features of claim 19.

### SUMMARY OF THE INVENTION

The electronic module comprises at least one functional circuit component, a module body, a first interface configured to electrically connect to a power module and a second interface configured to electrically connect to a power supply. The electronic module further comprises a first capacitance unit configured to reduce an extended high-frequency noise and a second capacitance unit configured to reduce an external low-frequency noise such that the first and second capacitance units form an electromagnetic compatibility (EMC) filter structure. The first and second capacitance units and the functional circuit component are integrated in the module body.

The functional circuit component is in particular a component of the electronic module which determines the functionality of the electronic module. The functional circuit component may be, for example, at least one DC-link circuit comprising in particular at least one DC-link capacitor. In this case the electronic module is a DC-link module. Preferably, the DC-link capacitor is a thin-film capacitor.

It is possible that the functional circuit element component a plurality of DC-link circuits. For example the DC-link circuits are formed as individual components that are connected together to form the functional circuit component. By forming the functional circuit component with a plurality of DC-link circuits the properties of the functional circuit component can be advantageously tuned.

The module body in particular determines the dimensions of the electronic module. In particular, surfaces of the electronic module accessible from the outside determine the module body. Integrating the first capacitance unit and the second capacitance unit together with the functional circuit component in the module body enables a reduction of the size of the electronic module. In particular, a footprint of the electronic module may be decreased. In turn, also a weight of the electronic module may be decreased.

By the first interface, a power module can be connected to the electronic module. For example, the first interface comprises a plurality of electronic contacts. In particular, the first interface comprises at least two electronic contacts carrying different electric potentials. For example, the first interface may comprise four or six electronic contacts, wherein each two of the electronic contacts form a pair carrying different electronic potentials.

By the second interface, a power supply can be connected to the electronic module. For example, the second interface comprises a plurality of electronic contacts. In particular, the second interface comprises at least two electronic contacts carrying different electric potentials.

If, for example, the electronic module is a DC-link module, the power module may be an inverter and the power supply may be a high voltage battery (HV-battery) with a high voltage DC output. Such an arrangement of a HV-battery, a DC-link module and an inverter are used, for example, in a motor circuit configuration.

Usually, state of the art inverters comprise semiconductor switches to convert the DC voltage of the HV-battery in an AC voltage suitable for a following application such as a motor drive. During operation these switches cause noise comprising high-frequency and low-frequency components at the DC-link module. Since the inverter operates at a comparably large current, an intensity of the noise may be relatively big. Conventionally, an EMC filter element is therefore additionally needed at the power input side of the DC-link module in order to reduce the noise caused by a switching power module over the DC-link to the power supply, such as the high-voltage battery. This EMC filter element is usually a discrete entity connected to the DC-link module by electrical wires or leads. Consequently, this EMC filter element requires additional space and the electrical wires or leads cause additional equivalent series inductance, which reduces the filter performance.

The electronic module described herein makes use of the idea of integrating a first capacitance unit and a second capacitance unit that form an EMC filter structure inside the module body of the electronic module, wherein the functional circuit component, such as a DC-link circuit component, is also arranged. Consequently, additional EMC filter elements can be omitted and the size and the weight of the electronic module can be reduced. Furthermore, the usage of electrical leads may be reduced or completely avoided, significantly reducing parasitic inductances and resistances, also known as equivalent series inductances (ESL) and resistance (ESR).

Preferably the electronic module is free of a circuit board or the like. This means in particular that all components of the electronic module, such as the first and second capacitance units, the first and second interfaces as well as the functional circuit component are directly electrically connected. By “directly electrically connected” it is meant in particular that the electrical connection is made without a wire or an electrical lead. For example, different entities that are directly electrically connected may be in direct physical contact, i.e. touching each other. For example, elements or components of the electronic module may be directly connected, in particular directly electrically connected, by soldering or welding or the like. In the following directly electrical connections may also be referred to as “lead-free”.

Since the first capacitance unit is configured to reduce an external high-frequency noise and the second capacitance unit is configured to reduce an external low-frequency noise, noise that emerges from other electrical entities used together with the electronic module during operation, such as the power module or the power supply, can be efficiently reduced over a large frequency range. To achieve this, each of the first and second capacitance units preferably comprises at least one capacitor whose capacitance is adapted to the high-frequency and low-frequency components of the noise, respectively.

The first capacitance unit may be electrically arranged between the first interface and the functional circuit component and the second capacitance unit may be electrically arranged between the second interface and the functional circuit component. That is in particular, an output of the first capacitance unit may be electrically connected to the first interface and an input of the first capacitance unit may be electrically connected to an output of the functional circuit component. Furthermore, the second interface may be electrically connected to an input of the second capacitance unit and an output of the second capacitance unit may be electrically connected to an input of the functional circuit component. Preferably all electrically connections between the first and second interfaces, the first and second capacitance units, and the functional circuit components are direct electrical connections.

Preferably, the first capacitance unit comprises at least one first flat-plate capacitor and the second capacitance unit comprises at least one second flat-plate capacitor. In particular, each of the flat-plate capacitors are connected to a ground contact of the electronic module. That is, the flat-plate capacitors are preferably CY capacitors.

Preferably, the first capacitance unit comprises a pair of first flat-plate capacitors and the second capacitance unit comprises a pair of second flat-plate capacitors. Here and in the following it is understood that features disclosed for the at least one first flat-plate capacitor and/or the at least one second flat-plate capacitor are accordingly also disclosed for the pair of first flat-plate capacitors and/or the pair of second flat-plate capacitors, respectively, and vice versa.

In particular, the at least one first flat-plate capacitor at least partially forms a first side surface of the module body. Preferably, the first side surface is essentially completely formed with the at least one first flat-plate capacitor.

In particular, the first interface is arranged at the first side surface of the module body. In this case, the at least one first flat-plate capacitor is arranged between the functional circuit component and the first interface. That is, the at least one first pair of capacitors is arranged between the functional circuit component and the power module, if a power module is connected to the first interface. If the power module is a source for noise, the EMC filter structure of the electronic module is arranged closer to the noise source than in comparable conventional systems, where the EMC filter element is arranged on the side of a power input. Thus, an EMC of the electronic module can be increased.

Furthermore, the at least one second flat-plate capacitor may at least partially form a top surface of the module body. Preferably, the top surface is essentially completely formed with the at least one second flat-plate capacitor.

In a circuit configuration representing the electronic module the second interface is connected to the functional circuit component, for example, by two power lines, wherein each power line carries a different electronic potential. If the functional circuit component comprises a DC-link capacitor, the DC-link capacitor is preferably arranged between the power lines, i.e. in parallel to the second interface. The functional circuit component may be further electrically connected to the first interface by the power lines. The first capacitance unit may be arranged between the first interface and the functional circuit component. For example, each power line is connected to ground via one capacitor of the first capacitance unit. The second capacitance unit may be arranged between the second interface and the functional circuit component. For example, each power line is connected to ground via one capacitor of the second capacitance unit. The capacitors of the first and second capacitance units are preferably flat-plate capacitors.

By using flat-plate capacitors, the first capacitance unit and the second capacitance unit can be formed particularly thin and therefore space-saving. This allows for a miniaturization of the electronic module. If, additionally, the at least one first flat-plate capacitor forms at least a part of the first side surface of the module body and the at least one second flat-plate capacitor forms at least a part of the top surface of the module body, a plurality of advantages can be achieved.

For example, the first and second flat-plate capacitors may form an additional shielding against perturbing noise for the functional circuit component. In particular, such a shielding may efficiently reduce a noise field coupling.

Furthermore, the first and second flat-plate capacitors may dissipate heat from the functional circuit component generated during operation. Heat may, for example, be generated during operation due to an equivalent serial resistance (ESR) of the functional circuit component and/or due to a so-called ripple current. Consequently, the amount of additional cooling means may be reduced or the dissipation of heat may be increased, compared to comparable conventional electronic modules requiring a discrete EMC filter element. This may result in a smaller electronic module or in an electronic module with an increased performance, respectively.

Further, the first and second flat-plate capacitors can be advantageously arranged particularly space-saving if each of the first and second pair of flat-plate capacitors forms at least a part of an outer surface of the module body. Hence, this enables the size of the electronic module to be further reduced.

For example, each of the at least one first and second flat-plate capacitors are formed by a printed circuit board (PCB). That is, the at least one first capacitor and the at least one second capacitor are each preferably formed by a layer structure comprising at least two electrically conductive layers alternating with at least one electrically insulating layer. The electrically insulating layers of the printed circuit board comprise, for example, an aluminum nitride substrate, a ceramic material and/or FR4 and/or capacitances using high permittivity material. In particular, optimum values of capacitance, ESL and ESR of the first and second flat-plate capacitors are related to the materials of insulating layers and layout design of the electrically conductive layers.

By forming each of the first and second flat-plate capacitors by a printed circuit board, the first and second flat-plate capacitors can be formed particularly thin and advantageously at a low cost. Furthermore, the material of the insulating layers of the printed circuit board can be chosen such that, for example, an effective heat dissipation can be carried out by the first and second flat-plate capacitors, while a capacitance of the capacitors is suitable for noise attenuation. In addition, printed circuit boards may be easily applied to the functional circuit component, in particular with little or no need for electrical wires or leads.

It is possible that at least one electric component is arranged on the at least one printed circuit board forming at least one of the first flat-plate capacitor and/or second flat-plate capacitor. For example, additional discrete passive components like capacitances or active filter circuits may be arranged on the printed circuit board. Such additional components may increase noise reduction of the first and second capacitance units.

The electronic module may further comprise a choke. Preferably, the choke is at least partially integrated in the module body. The choke is in particular electrically connected to the functional circuit component and the second capacitance unit. For example, the choke is arranged in a circuit configuration of the electronic module between the functional circuit component and the second capacitance unit. In particular the choke is part of the EMC filter structure.

The choke is in particular a common mode choke (CMC). In this case the choke is configured to attenuate perturbing electromagnetic interference and/or radiofrequency interference frequencies. That is, by using a choke, perturbing noise for the functional circuit component can be further reduced.

Preferably, the first capacitance unit comprises a capacitance of 1 nF or less and the second capacitance unit comprises a capacitance between 1 nF and 500 nF. If, for example, the first capacitance unit comprises at least one first flat-plate capacitor, each of the at least one first flat-plate capacitors comprises a capacitance of 1 nF or less. If, for example, the second capacitance unit comprises at least one second flat-plate capacitor, each of the at least one second flat-plate capacitors comprises a capacitance between 1 nF and 500 nF.

Advantageously, a capacitance unit comprising a capacitance of 1 nF or less is particularly effective for attenuating a high-frequency noise including frequencies above 50 MHz. In turn, a capacitance units comprising a capacitance between 1 nF and 500 nF is particularly effective for attenuating a low-frequency noise including frequencies below 50 MHz. That is, by using a combination of the first capacitance unit comprising a capacitance of 1 nF or less, and the second capacitance unit comprising a capacitance between 1 nF and 500 nF, noise over a large range of frequencies can be covered by the first and second capacitance units.

Preferably, the first capacitance unit is lead-free connected to the first interface. Alternatively or additionally the second capacitance unit is lead-free connected to the second interface. For example, the first capacitance unit and the first interface and/or the second capacitance unit and the second interface are electrically directly connected to each other. In particular, the first/second capacitance unit is arranged in the vicinity of the first/second interface such that the first/second capacitance unit can be directly connected to the first/second interface, for example by soldering or welding or the like. That is, an electric wire or lead may advantageously be omitted. Consequently, parasitic inductance, i.e. an ESL, can be reduced. Hence, the performance of the electronic module can be increased.

Advantageously, the first and/or second capacitance unit can also shield the electronic module from high-frequency noise, such as high-frequency switching noise, caused by the power module.

The electronic module may further comprise at least one cooling plate surrounding the functional circuit component. In particular, the cooling plate is arranged between the functional circuit component and the top surface, between the functional circuit component and the first side surface, and the functional circuit component and a second side surface opposite to the first side surface. Preferably, the cooling plate is connected to the cooling body arranged at the bottom surface of the module body.

The cooling body at least partially may form the bottom surface. In particular, the bottom surface of the module body is opposite to the top surface of the module body. It is possible that, in view of the bottom surface, the cooling body completely covers the functional circuit component.

In particular, the cooling plate is configured to dissipate heat of the electronic module to the bottom surface. That is in particular, the heat is dissipated to the cooling body. The cooling body may further be connected to an external heat sink or the like.

The cooling body may comprise, for example, a heat dissipation plate configured to dissipate heat from the electronic module. It is possible that the cooling body is formed by the heat dissipation plate. Preferably, the heat dissipation plate is formed with a metal plate and comprises, for example, copper or aluminum. A thickness of the heat dissipation plate may be approximately or essentially the same as a thickness of the cooling plate. In particular, the heat dissipation plate is connected to an external heat sink. That is, the heat dissipation plate is configured to dissipate heat from the electronic module, in particular the functional circuit component, to the external heat sink. The external heat sink may be a cooling element of a power module connected to the electronic module. Preferably, the heat dissipation plate is electrically insulated from the electronic module and/or at least some or all components of the electronic module.

By using a heat dissipation plate the electronic module can advantageously be free of a heat sink. In particular, if the electronic module is used together with a power module, the cooling element of the power module can be used as a heat sink for the electronic module. This reduces the space the electronic module needs and costs of the electronic modules since expensive and space-consuming heat sinks for the electronic module may be omitted.

Additionally or alternatively it is possible that the heat dissipation plate is connected to a heat sink arranged at the bottom surface of the electronic module.

Heat may be, for example, generated during operation due to an equivalent serial resistance (ESR) of the functional circuit component and/or due to a so-called ripple current. Comparable conventional electronic modules such as conventional DC-link modules only comprise a cooling element at the bottom surface. By additionally arranging a cooling plate surrounding the function of primary circuit, heat can be more efficiently dissipated. Therefore, the performance of the electronic module may be increased. Additionally or alternatively, the size of the electronic module maybe reduced since heat can be more efficiently dissipated.

The cooling plate preferably comprises an electrically conductive material with a high thermal conductivity coefficient. For example, the cooling plate comprises at least one metal such as copper, aluminum and/or iron.

Preferably the cooling plate comprises aluminum or is made of aluminum. Advantageously, by using aluminum for the cooling plate, the weight of the electronic module can be kept comparably low.

Alternatively or additionally, the cooling plate may comprise a ceramic material. In this case it is possible that the ceramic material forms a matrix material in which filler particles for adapting physical properties such as heat or electrical conductance are integrated.

In particular, in the case that the first capacitance unit comprises at least one first flat-plate capacitor and/or the second capacitance unit comprises at least one second flat-plate capacitor, the cooling plate is at least partially arranged between the functional circuit component and at least one of the at least one first flat-plate capacitor and the at least one second flat-plate capacitor. In this preferred configuration the functional circuit component is, for example, covered by the at least one first flat-plate capacitor in view of the first side surface, by the at least one second flat-plate capacitor in view of the top surface, by the cooling plate in view of the second side surface, and by the cooling body in view of the bottom surface.

Preferably, a grounding contact of each of the first capacitance unit and the second capacitance unit is directly connected to the cooling plate. For example, each capacitor of the first and second capacitance unit comprise a grounding contact structure which is directly connected to the cooling plate. That is, the cooling plate serves as a grounding element for the first capacitance unit and the second capacitance unit. “Directly connected” in this context means in particular that the first and the second capacitance units are each in direct physical contact and direct electrical contact with the cooling plate. In particular this enables an electrical connection between the first and second capacitance unit and the cooling plate to be lead-free.

It is possible that the cooling plate covers the functional circuit component completely in view of the top surface and in view of the first side surface. Preferably, the cooling plate is configured to reduce noise coupling to the functional circuit component. In other words, the cooling plate acts as a shielding for the functional circuit component.

The cooling plate may be fixedly connected to the cooling body by means of a connection means. Preferably, the connection means comprises an electrically conductive material such that the cooling body is electrically conductively connected to the cooling plate. The connection means is, for example, at least one screw. The at least one screw may comprise steel. Additionally, the connection means is configured to dissipate heat from the cooling plate to the cooling body.

Preferably, each of the first and second capacitance units is electrically lead-free connected to the cooling body via the cooling plate. In particular, the cooling body serves as a ground contact for the first capacitance unit and the second capacitance unit. Preferably, the cooling body is a ground contact for the whole electronic module. For example, each of the first and second capacitance units is directly electrically conductively connected to the cooling plate and the cooling plate is electrically connected to the cooling body via the connection means. That is, no electrical wires or leads are needed to connect the first and second capacitance unit to the ground. Advantageously, this reduces the ESL of the electronic module.

Furthermore, electromagnetic fields that are induced in the cooling plate due to noise coupling can be effectively dissipated to the cooling body, i.e. to the ground contact of the electronic module. Additionally or alternatively, electromagnetic fields that are induced in the first and second capacitance units can also be dissipated to the cooling body by the cooling plate. For example, such electromagnetic fields may be induced in the flat-plate capacitors of the first and second capacitance units.

Furthermore, an arrangement is specified. In particular, the arrangement comprises an electronic module described herein. That is, all features disclosed for the electronic module are also disclosed for the arrangement and vice versa.

The arrangement may comprise a power module and a power source. The power module may be connected to the first interface of the electronic module and the power source may be connected to the second interface of the electronic module. For example, the arrangement is a part of a motor circuit, in particular configured to power an electronic motor drive. In this case, the power supply may be a HV-battery, the electronic module may be a DC-link module and the power module may be an inverter.

It is possible that the power module comprises a semiconductor material. The semiconductor material may be based on silicon, silicon carbide and/or gallium nitride technology. In particular, the semiconductor material may be used for switches of the power module.

In particular, the power module may be a power module comprising one or more switches.

The semiconductor material may be a wide band gap (WBG) semiconductor material. Such WBG semiconductors are used, for example, for switches of the power module, i.e. the inverter. Particularly short switching times can be achieved by using WBG semiconductors. However, such switching times particularly produce a high-frequency noise. By using the cooling plate in combination with the first and second capacitance unit, such high-frequency noise can also be efficiently reduced and suppressed such that the functional circuit component is protected against such noise. Examples for WBG semiconductor materials are SiC or GaN.

Further advantages and advantageous embodiments and further developments of the electronic module and the arrangement will become apparent from the following exemplary embodiments shown in connection with schematic drawings. Identical elements, elements of the same kind or elements having the same effect, are provided with the same reference signs in the figures. The figures and the proportions of the elements shown in the figures are not to be regarded as true to scale. Rather, individual elements may be shown exaggeratedly large for better representability and/or for better comprehensibility.

### BRIEF DESCRIPTION OF THE DRAWINGS

In the figures:

FIGS. 1 to 4 show an electronic module described herein in different views according to an exemplary embodiment;

FIG. 5 illustrates a circuit configuration of an electronic module described here according to an exemplary embodiment;

FIGS. 6 and 7 show diagrams illustrating attenuation of noise achieved by the electronic module described herein;

FIG. 8 shows a schematic illustration of an arrangement described herein according to an exemplary embodiment;

FIG. 9 shows a schematic sectional view illustrating a cooling of an arrangement described herein according to an exemplary embodiment.

### DETAILED DESCRIPTION OF THE DRAWINGS

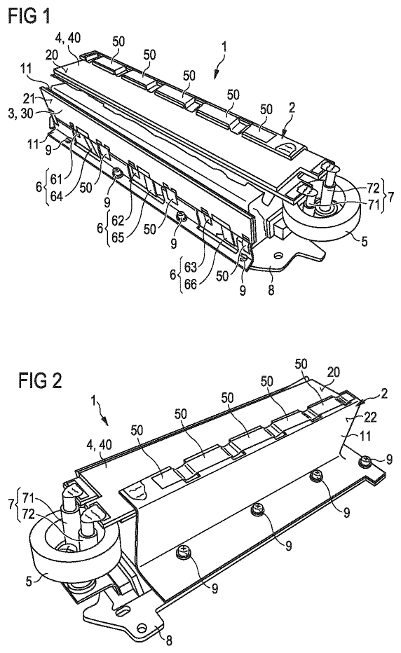

FIGS. 1 to 4 shows an electronic module 1 described herein according to an exemplary embodiment in different perspective views. The electronic module 1 comprises a module body 2.

A first side surface 21 of the module body 2 is formed with a first capacitance unit 3. The first capacitance unit 3 comprises a pair of first flat-plate capacitors 30 (see FIGS. 1 and 3). The pair of first flat-plate capacitors 30 is directly electrically connected to a first interface 6. The first interface 6 is configured to form an electrical connection to a power module (not shown) by a first to sixth electrical contact 61 to 66 of the first interface 6. The power module is, for example, an inverter.

A top surface 20 of the module body 2 is formed with a second capacitance unit 4 (see FIGS. 1 to 3). The second capacitance unit 4 comprises a pair of second flat-plate capacitors 40. The pair of second flat-plate capacitors 40 is directly electrically connected to a second interface 7. The second interface 7 is configured to form an electrical connection to a power supply (not shown) by a first electrical contact 71 and a second electrical contact 72. The power supply is, for example, a HV-battery.

The flat-plate capacitors 30, 40 of the first and second capacitance units 3, 4 are formed with printed circuit boards (PCB), in particular as multilayered PCBs. Electrically insulating layers of printed circuit boards are, for example, formed with FR4 or a ceramic material.

The electronic module 1 further comprises a choke 5. The choke 5 is partially arranged inside the module body 2 and is a common mode choke 5. Together with the first capacitance unit 3 and the second capacitance unit 4, the choke 5 forms an EMC filter structure.

Inside the module body 2, the electronic module 1 comprises a functional circuit component 10 (see FIG. 3). The functional circuit component 10 determines the electrical function ability of the electronic module 1. For example, the functional circuit component 10 comprises a DC-link capacitor 10a. That is, the electronic module 1 is a DC-link module. The DC link capacitor 10a is preferably a thin-film, ceramic or electrolyte capacitor or other capacitances using high permittivity material.

The EMC filter structure is configured to protect the functional circuit component 10, and in particular the DC-link capacitor 10a, from external noise. In other words, the EMC filter structure is configured to increase an EMC of the DC-link capacitor 10a. Such noise may have low-frequency and high-frequency components.

In particular, low-frequency noise comprises frequencies of 50 MHz or less and high-frequency noise comprises frequencies of 50 MHz or more. To achieve said protection, capacitors of the first capacitance unit 3 each comprise a capacitance of 1 nF or less and are configured to attenuate high-frequency components of the noise. Furthermore, capacitors of the second capacitance unit 4 each comprise a capacitance between 1 nF and 500 nF and are configured to attenuate low-frequency components of the noise.

Optimum values of the capacitance, ESL and ESR of first and second flat-plate capacitors are in particular related to the materials of insulating layers and layout design of the electrically conductive layers, related to the printed circuit board.

By forming the first capacitance unit 3 as the top surface 20 of the module body 2 and the second capacitance unit 4 as the first side surface 21 of the module body 2, the EMC filter structure can be integrated in the module body 2. That is, the additional distinct EMC filter elements that are conventionally used in comparable DC-link applications can be omitted. As a result, the size and weight of the electronic module 1 can be significantly reduced and efficient noise attenuation can be achieved at the same time.

In particular, the electronic module 1 is free of a circuit board on which the first and second capacitance units 3, 4 and the functional circuit component 10 would be arranged.

Instead, the first and second capacitance units 3, 4 are directly connected to the functional circuit component 10. Since the first and second capacitance units 3, 4 are additionally directly connected to the first interface 6 and the second interface 7, the electronic module 1 can be formed essentially free of wires or electrical leads. As a result, parasitic inductance, also known as equivalent serial inductance (ESL), of the electronic module 1 is significantly reduced.

A cooling plate 11 is arranged between the functional circuit component 10 and the first and second capacitance units 3, 4. The cooling plate 11 is formed with a highly thermal conductive material such as copper, iron, and/or aluminum. Preferably, the cooling plate 11 is formed of an electrically conductive material such as a metal. The cooling plate 11 completely covers the functional circuit component 10 in view of the first side surface 21, in view of the second side surface 22 opposite to the first side surface 21, and in view of the top surface 20 (see FIGS. 1 and 2).

In an alternative exemplary embodiment, the cooling plate 11 may be omitted. In this case, the first and/or second capacitance unit 3, 4 can advantageously shield the electronic module 1 from high-frequency noise, such as high-frequency switching noise, emitted from the power module. In particular, the electronic module 1 may be a DC-link capacitance and the power module 91 may be a switching module in this alternative exemplary embodiment.

A cooling body 8 is arranged at a bottom surface 23 of the module body 2 opposite to the top surface 20. The cooling body 8 preferably covers the functional circuit component 10 in view of the bottom surface 23 (see FIG. 4). The cooling plate 11 is connected to the cooling body 8 by a connection means 9, which are screws 9 in the present exemplary embodiment. The screws 9 form both a fixed connection and an electrical connection between the cooling plate 11 and the cooling body 8.

The cooling plate 11 allows for an increased dissipation of heat of the functional circuit component 10. Since the cooling plate 11 is arranged in the vicinity of the functional circuit component 10 and connected to the cooling body 8, the cooling plate 11 forms a heat dissipation path for heat generated in the functional circuit component 10 during operation. Such heat may emerge from an ESR of the functional circuit component 10 and/or a so-called ripple current. Furthermore, since the cooling plate 11 covers the functional circuit component 10 on at least three sides, heat dissipation is particularly effective.

Furthermore, the cooling plate 11 serves as a shielding for the functional circuit component 10 which reduces or attenuates the noise coupling of the functional circuit component 10.

The cooling body 8 is in particular at ground potential. Since the cooling plate 11 is electrically connected to the cooling body 8, the cooling plate 11 is also at ground potential. Grounding contact structures 50 of the first and second capacitance units 3, 4 are directly electrically connected to the cooling plate 11. Hence, the first and second capacitance units 3, 4 are lead-free grounded by the cooling plate 11 connected to the cooling body 8. Hence, if external noise induces an electromagnetic field in the cooling plate 11, the first capacitance unit 3 and/or the second capacitance unit 4, this noise field can be dissipated by the cooling plate 11 and the cooling body 8.

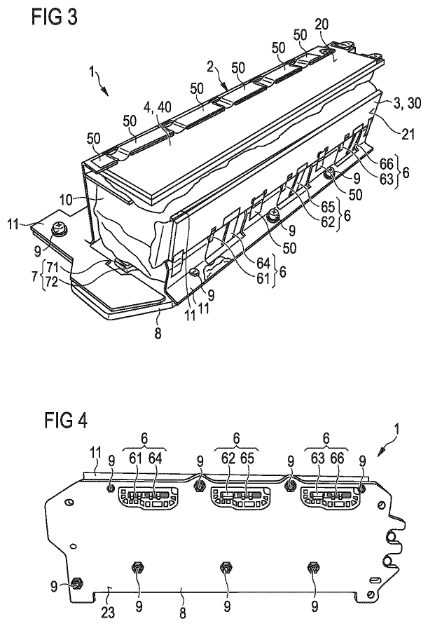

FIG. 5 shows a circuit configuration of an electronic module 1, in particular of the electronic module 1 according to FIGS. 1 to 4. The first capacitance unit 3 is arranged between the first interface 6 and the functional circuit component 10 comprising the DC-link capacitor 10a. The first capacitance unit 3 comprises the pair of first flat-plate capacitors 30. The choke 5 is arranged between the functional circuit component 10 and the second capacitance unit 4 comprising the pair of second flat-plate capacitors 40. The second capacitance unit 4 is arranged between the choke 5 and the second interface 7.

The first interface 6 is connected to the functional circuit component 10 by a first power line 12 and a second power line 13. Since the electronic module 1 is in particular free of a circuit board, the lines showing the power lines 12, 13 in FIG. 5 are in particular to be understood as purely illustrative and not to be understood as showing the presence of any electrical wire or lead connecting the different components. The DC-link capacitor 10a is arranged between the power lines 12, 13 in the functional circuit component 10.

Each of the first and second flat-plate capacitors 30, 40 is connected to one of the power lines 12, 13 and the ground 80. That is, the first and second flat-plate capacitors 30, 40 are CY capacitors. The ground 80 is formed in particular by the cooling plate 11 together with the cooling body 8.

The second interface 7 is connected to the functional circuit component 10 by the power lines 12, 13.

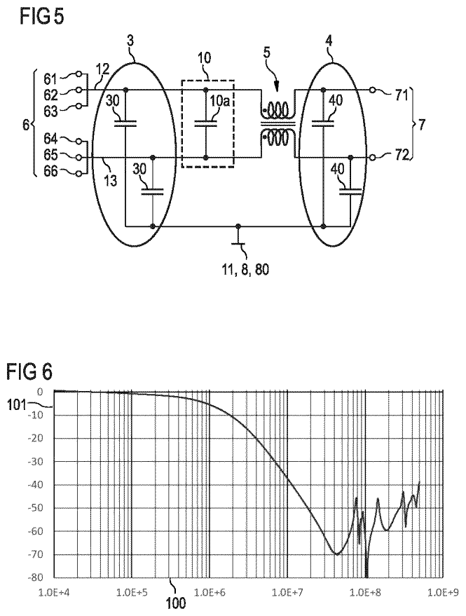

FIGS. 6 and 7 show attenuation diagrams illustrating an attenuation of external noise by the EMC structure of the electronic module 1. The diagram of FIG. 6 shows a damping 101 of noise in dB as a function of frequency 100 in Hz in common mode. As can be seen, noise frequencies above 0.2 MHz are damped by the EMC filter structure comprising the first and second capacitance units 3, 4 and the choke 5. Attenuation of noise increases with a frequency of up to about 300 MHz. Above this frequency, the damping value 101 decreases, but remains below about −40 dB. That is, an efficient attenuation of noise over a wide frequency range is possible by the electronic module 1. This damping value is related to the performance of the choke 5 and the first and second capacitance units 3, 4.

The diagram of FIG. 7 shows a damping 101 of noise in dB as a function of frequency 100 in Hz in differential mode. As can be seen, the damping value 101 remains below about −40 dB of all frequencies. That is, an efficient attenuation of noise over a wide frequency range is possible by the electronic module 1.

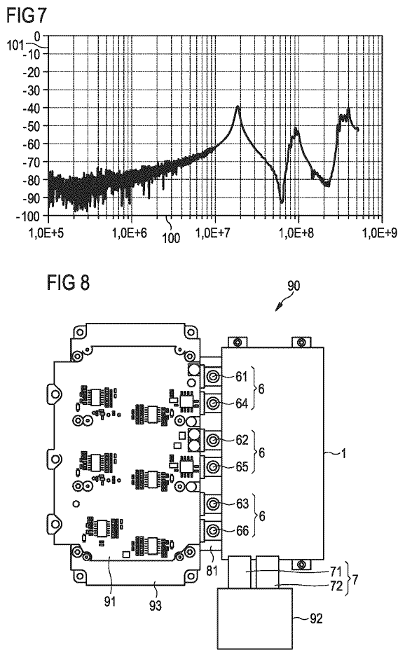

FIG. 8 illustrates an arrangement 90 described herein according to an exemplary embodiment. The arrangement 90 comprises an electronic module 1 which is, in particular, the electronic module 1 according to the exemplary embodiment of FIGS. 1 to 4. At the second interface 7 the electronic module 1 is electrically connected to a power supply 92. In the present example the power supply 92 is a HV-battery.

At the first interface 6 a power module 91 is electrically and mechanically connected to the electronic module 1. The power module 91 is, for example, an inverter. The power module 91 may include a plurality of switches comprising a wide bandgap semiconductor material. Each of the first to sixth electrical contact 61 to 66 of the first interface 6 is connected to a counterpart at the power module 91.

If the electronic module 1 is a DC-link module, the arrangement 90 is, for example, part of a motor circuit. In this case, the power supply 92 provides a DC current to the power module 91 via the electronic module 1. This DC current is converter in an AC current by the power module 91. Subsequently, the AC current is provided to a motor drive (not shown). The electronic module 1 then serves in particular as a buffer, for example an energy buffer, and is also known as a DC-link module. During operation the switches of the power module 91 generate a noise that may be coupled to the electronic module 1. This noise may reduce the performance of the electronic module 1. This noise is attenuated by the EMC filter structure of the electronic module 1 comprising the first capacitance unit 3 and the second capacitance unit 4. Thereby, an EMC of the electronic module 1 is improved.

The power module 91 comprises a heat sink 93 for dissipating heat generated during operation of the power module 91. The heat sink 93 is arranged on an underside of the power module 91. Optionally, the heat sink 93 may be connected to a cooling body 8 of the electronic module 1 by a heat dissipation plate 81 of the cooling body 8. The heat dissipation plate 81 is configured to dissipate heat generated by the electronic module 1 to the heat sink 93 of the power module 91. Hence, dissipating of heat from the electronic module 1 can be increased. Preferably, the heat dissipation plate 81 is electrically insulated from the first interface 6.

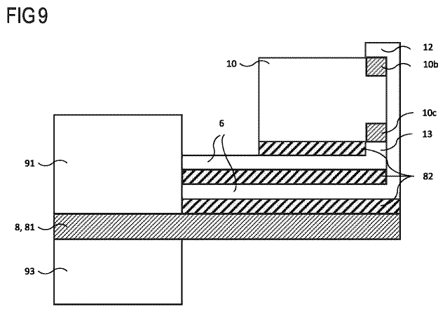

A sectional plane of the sectional view of FIG. 9 is perpendicular to the bottom surface 23 and the first side surface 21 of the electronic module 1. For illustrational purposes the cooling plate 11 as well as the first and second capacitance units 3, 4 are omitted in FIG. 9.

In the exemplary embodiment of FIG. 9 a cooling body 8 of an electronic module 1 is formed as a heat dissipation plate 81. The heat dissipation plate 81 is electrically insulated from the first interface 6 by electrically insulating layers 82.

The power module 91 comprises a heat sink 93 at an underside. That is, the heat sink 93 is an external heat sink for the electronic module 1. The heat dissipation plate 81 is connected to the heat sink 93. In particular, the heat dissipation plate 81 is configured to dissipate heat generated during operation of the electronic module 1, i.e. the functional circuit component 10, to the heat sink 93. This advantageously allows that the electronic module 1 can be constructed free of a heat sink. Hence, space, weight and costs for the electronic module 1 can be reduced if the electronic module 1 can be formed without a distinct heat sink.

The invention is not restricted to the exemplary embodiments of the description on the basis of said exemplary embodiments. Rather, the invention encompasses any new feature and also any combination of features which in particular comprises any combination of features in the patent claims and any combination of features in the exemplary embodiments, even if this feature or this combination itself is not explicitly specified in the patent claims or exemplary embodiments.

### REFERENCES

1 electronic module
2 module body
3, 4 first, second capacitance unit
5 choke
6, 7 first, second interface
8 cooling body
9 connection means
10 functional circuit component
10a DC-link capacitor
10b terminal first power line
10c terminal second power line
11 cooling plate
12, 13 first, second power line
20 top surface
21, 22 first, second side surface
23 bottom surface
30, 40 first, second flat-plate capacitor
50 grounding contact structure
61 . . . 66 first to sixth electrical contact of first interface
71, 72 first and second electrical contact of second interface
80 ground
81 heat dissipation plate
82 electrically insulating layer
90 arrangement
91 power module
92 power supply
93 heat sink
100 frequency in Hz
101 damping in dB

1-20. (canceled)

21. An electronic module comprising:
at least one functional circuit component;
a module body;
a first interface configured to electrically connect to a power module;
a second interface configured to electrically connect to a power supply;
a first capacitance unit configured to reduce an external high-frequency noise and a second capacitance unit configured to reduce an external low-frequency noise such that the first and second capacitance units form an EMC filter structure, and
wherein the first capacitance unit, the second capacitance unit and the functional circuit component are integrated in the module body.

22. The electronic module according to claim 21, wherein the first capacitance unit is electrically arranged between the first interface and the functional circuit component, and wherein the second capacitance unit is electrically arranged between the second interface and the functional circuit component.

23. The electronic module according to claim 21, wherein the first capacitance unit comprises at least one first flat-plate capacitor and the second capacitance unit comprises at least one second flat-plate capacitor.

24. The electronic module according to claim 23, wherein the at least one first flat-plate capacitor at least partially forms a first side surface of the module body, and wherein the at least one second flat-plate capacitor at least partially forms a top surface of the module body.

25. The electronic module according to claim 23, wherein each of the at least one first and the at least one second flat-plate capacitors is formed by a printed circuit board.

26. The electronic module according to claim 25, wherein at least one electric component is arranged on at least one of the printed circuit boards.

27. The electronic module according to claim 21, further comprising a choke, wherein the choke is integrated in the module body.

28. The electronic module according to claim 21, wherein the first capacitance unit comprises a capacitance of 1 nF or less, and wherein the second capacitance unit comprises a capacitance between 1 nF and 500 nF.

29. The electronic module according to claim 21, wherein the first capacitance unit is lead-free connected to the first interface and the second capacitance unit is lead-free connected to the second interface.

30. The electronic module according to claim 21, wherein the functional circuit component is a DC-link circuit and the electronic module is a DC-link module.

31. The electronic module according to claim 21, further comprising at least one cooling plate at least partially surrounding the functional circuit component, wherein the cooling plate is connected to a cooling body arranged at a bottom surface of the module body, and wherein the cooling plate is configured to dissipate heat of the electronic module to the bottom surface.

32. The electronic module according to claim 31, wherein the first capacitance unit comprises at least one first flat-plate capacitor and the second capacitance unit comprises at least one second flat-plate capacitor, and wherein the cooling plate is at least partially arranged between the functional circuit component and at least one of the at least one first flat-plate capacitor and the at least one second flat-plate capacitor.

33. The electronic module according to claim 31, wherein a grounding contact of each of the first capacitance unit and the second capacitance unit is directly connected to the cooling plate.

34. The electronic module according to claim 31, wherein the cooling plate covers the functional circuit component completely in view of the top surface and the first side surface, and wherein the cooling plate is configured to reduce noise coupling to the functional circuit component.

35. The electronic module according to claim 31, wherein the cooling plate is fixedly connected to the cooling body by a connection means.

36. The electronic module according to claim 35, wherein the connection means comprises an electrically conductive material, such that the cooling body is electrically conductively connected to the cooling plate, and wherein the cooling body is configured to provide a ground contact for the electronic module.

37. The electronic module according to claim 35, wherein each of the first and second capacitance units is electrically lead-free connected to the cooling body via the cooling plate.

38. The electronic module according to claim 31, wherein the cooling body comprises a heat dissipation plate, wherein the heat dissipation plate is configured to dissipate heat from the electronic module to an external heat sink, and wherein the external heat sink is a cooling element of the power module.

39. An arrangement comprising the electronic module according to claim 21, in combination with a power module and a power supply, wherein the power module is connected to the first interface of the electronic module, and wherein the power supply is connected to the second interface of the electronic module.

40. The arrangement according to claim 39, wherein the power module comprises a semiconductor material, and wherein the power module is an inverter configured to be additionally connected to a motor drive.
